(19) United States
(12) Patent Application Publication
(10) Pub. No.: US 2014/0084472 A1
(43) Pub. Date: Mar. 27, 2014

(54) COMPOUND DIELECTRIC ANTI-COPPER-DIFFUSION BARRIER LAYER FOR COPPER CONNECTION AND MANUFACTURING METHOD THEREOF

(71) Applicant: Fudan University, Shanghai (CN)

(72) Inventors: Qingqing Sun, Shanghai (CN); Runchen Fang, Shanghai (CN); Shan Zheng, Shanghai (CN); Wei Zhang, Shanghai (CN); Pengfei Wang, Shanghai (CN); Peng Zhou, Shanghai (CN)

(73) Assignee: Fudan University

(21) Appl. No.: 13/920,637

(22) Filed: Jun. 18, 2013

(30) Foreign Application Priority Data
Sep. 25, 2012 (CN) 201210362921.3

(51) Int. Cl. H01L 23/48; H01L 21/768; H01L 21/48

(52) U.S. Cl. CPC H01L 23/481; H01L 21/486; H01L 21/76877; H01L 21/76846
USPC 257/751; 438/627

(57) ABSTRACT

The disclosure belongs to the field of manufacturing and interconnection of integrated circuits, and in particular relates to compound dielectric anti-copper-diffusion barrier layer for copper interconnection and a manufacturing method thereof The disclosure uses compound dielectric (oxide & metal) as the anti-copper-diffusion barrier layer. First, it can enhance the capable of metal for anti-copper-diffusion efficiently, and prevent the barrier layer for valid owing to oxidized and prolong the life of the barrier layer. Second, it can reduce the effective dielectric constant of the interconnection circuits and furthermore reduce the RC delay of the whole interconnection circuits. Besides, the alloy is firmly adhered to the copper, and the metal copper can be directly electroplated without growing a layer of seed crystal copper. The method is simple and feasible and is expected to be applied to manufacturing of the anti-copper-diffusion barrier layers for copper interconnections.

### CROSS-REFERENCE TO RELATED APPLICATIONS

This application claims the benefit of and priority to Chinese Patent Application No. CN 201210362921.3 filed on Sep. 25, 2012, the entire content of which is incorporated by reference herein.

### BACKGROUND

1. Technical Field

The disclosure relates to an anti-copper-diffusion barrier layer and a manufacturing method thereof, in particular to a compound dielectric (oxide & metal) anti-copper-diffusion barrier layer for copper interconnection and a manufacturing method thereof, belonging to the field of manufacturing and interconnection of integrated circuits.

2. Background Art

Copper interconnection technology refers to a novel semiconductor manufacturing process substituting the copper metal material for the traditional aluminum metal material for interconnections during the manufacturing of the interconnection layer of the integrated semiconductor circuit. The traditional copper interconnection structure can be seen in FIG. 1, which comprises a low dielectric constant dielectric layer 11 formed on a semiconductor substrate 10, interconnection through-hole formed in the low dielectric constant dielectric layer 11, an anti-copper-diffusion barrier layer 12 covering the bottom walls and side walls of said interconnection through-hole, copper interconnection lines 13 formed in said interconnection through-hole and on said anti-copper-diffusion barrier layer 12, and a silicon nitride film formed on the copper interconnection lines 13 as an etching barrier layer and an insulator for the copper interconnection lines on the same layer. As mentioned above, before the copper electroplating, an anti-copper-diffusion barrier layer should be deposited to prevent the copper form diffusing into the dielectric, thus avoiding problems such as electric leakage.

With the reducing of the dimensions of the technical nodes of semiconductor, the requirement of the timing of the circuits becomes higher and higher, so there is a pressing need for new technology of reducing the RC (R refers to resistance, C refers to the capacitor) delay brought from interconnections itself, and, in essence, it needs to reduce the effective dielectric constant of the insulating layers in the interconnection. With the reduction of the technical node from 90 nm to the present 22 nm, to reducing the influence of the interconnection circuits, the Ultra-low K dielectric (ULK) is used as the insulating layers of the circuits, but it is very hard to keep the dielectric constant of the whole circuits in a very low level.

Currently, physical vapor deposition (PVD) is used for depositing the diffusion barrier layer. However, this process has the following disadvantages: the grown diffusion barrier layer is of low consistency and compactness; it is easily valid gradually owing to the oxidized when exposed to air or to the oxygen-containing gas, and to obtain high contact, the diffusion barrier layer must be subject to thermal annealing after being manufactured, but annealing will cause damage and negative influences to the manufactured devices; meanwhile, after the diffusion barrier layer is grown, a more layer of copper seed crystals is required to be deposited on the surface before the electroplating of the metal copper. The process is too complicated.

### SUMMARY

The objective of the present invention is to provide a novel diffusion barrier layer, which simplifies the process and meanwhile strengthen the performance of the diffusion barrier layer.

To fulfill the above objectives, the disclosure provides A compound dielectric anti-copper-diffusion barrier layer for copper connections, which comprises a low dielectric constant dielectric layer formed on a semiconductor substrate, interconnection through-hole formed in the low dielectric constant dielectric layer, which characterized in that,

a oxide layer covering the side walls of said interconnection through-hole and formed on the top of said low dielectric constant dielectric layer,

a metal layer covering the said oxide layer and the bottom wall of said interconnection through-hole,

and, the oxide & metal compound dielectric anti-copper-diffusion barrier layer are constituted by the said oxide layer and said metal layer.

Furthermore, the disclosure also provides a manufacturing method for a compound dielectric anti-copper-diffusion barrier layer for copper connections, comprising:

depositing a film of low dielectric constant dielectric layer on the surface of a provided semiconductor substrate;

spin-coating said low dielectric constant dielectric layer with the photoresist and photoetching to define the position of the interconnection through-hole;

etching said low dielectric constant dielectric layer to form interconnection through-hole, and removing the photoresist;

growing a thin oxide layer covering the side and bottom wall of said interconnection through-hole and oxide layer and the surface of the low dielectric constant dielectric layer;

etching said oxide layer to remove the part of said oxide layer covering the bottom wall of said interconnection through-hole;

depositing a metal layer covering the left oxide layer and the bottom wall of said interconnection through-hole,

and the oxide & metal compound dielectric anti-copper-diffusion barrier layer are constituted by the said oxide layer and said metal layer.

As the manufacturing method for a compound dielectric anti-copper-diffusion barrier layer for copper connections, said oxides layer may be silicon carbonitride (SiCN), silicon nitride (Si₃N₄), aluminum oxynitride (AlON), or alumina (Al₂O₃), tantalum oxide (Ta₂O₅), hafnium oxide (HfO₂) or other metal oxides.

As the manufacturing method for a compound dielectric anti-copper-diffusion barrier layer for copper connections, said metal layer may be elemental metal such as cobalt (Co), ruthenium (Ru), tantalum (Ta), wolfram (W), molybdenum (Mo), titanium (Ti), or copper (Cu), and also may be metal nitride such as tantalum nitride (TaN), titanium nitride (TiN) or molybdenum nitride (MoN).

The compound dielectric (oxide & metal) anti-copper-diffusion barrier layer for copper interconnection provided by the disclosure has the following advantages:

First, it can enhance the capable of metal for anti-copper-diffusion efficiently, and prevent the barrier layer for valid owing to oxidized and prolong the life of the barrier layer.

Second, it can reduce the effective dielectric constant of the interconnection circuits and furthermore it can reduce the RC delay of the whole interconnection circuits.

Third, the metal is firmly adhered to the copper, and the metal copper can be directly electroplated without growing a layer of seed crystal copper. The method is simple and feasible and is expected to be applied to manufacturing of the anti-copper-diffusion barrier layers for copper interconnections.

### BRIEF DESCRIPTION OF THE DRAWINGS

FIG. 1 is the sectional view of a copper interconnection structure in the prior art.

FIG. 2 is the sectional view of an embodiment of the compound dielectric anti-copper-diffusion barrier layer in the disclosure.

FIGS. 3-10 are flowcharts of a process embodiment for growing a SiCN/Ru compound dielectric anti-copper-diffusion barrier layer on the previous copper interconnection.

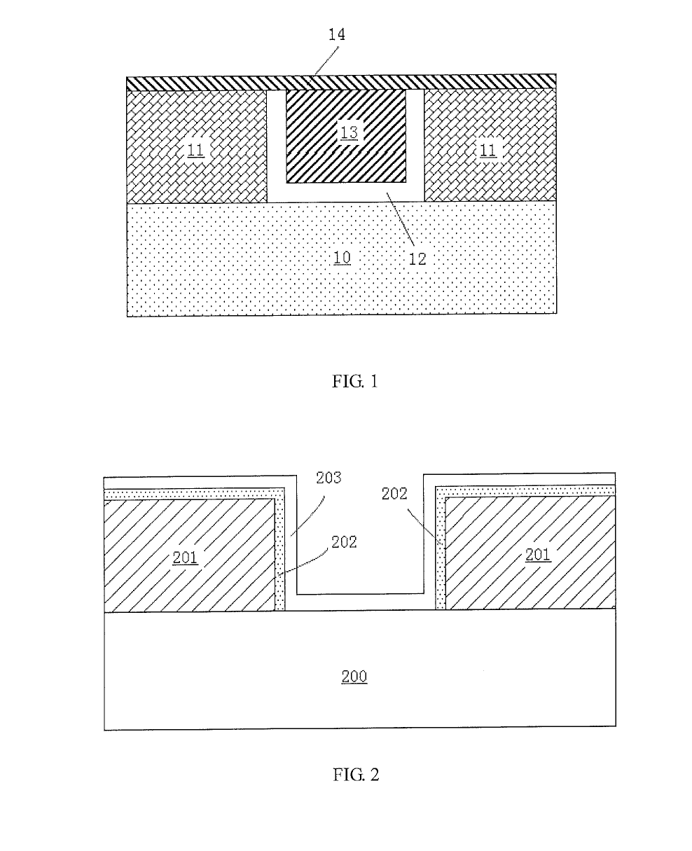

### DETAILED DESCRIPTION

The disclosure is further described in detail with reference to the attached drawings and the embodiment. In the figures, for convenience, the thicknesses of the layers and regions are amplified or reduced, and said dimensions do not represent the actual dimensions. The figures cannot completely and accurately reflect the actual dimensions of the devices, but they still completely reflect the mutual positions of the regions and the structures, in particular the vertical and neighbor relations between the structures.

FIG. 2 is the sectional view of an embodiment of the compound dielectric anti-copper-diffusion barrier layer in the disclosure. As shown in FIG. 2, a low dielectric constant dielectric layer 201 formed on a semiconductor substrate 200, interconnection through-hole formed in the low dielectric constant dielectric layer 201. An oxide layer 202 is formed on the side walls of the interconnection through-hole and formed on the top of the low dielectric constant dielectric layer 201, and a metal layer 203 is covering the oxide layer 202 and the bottom wall of the interconnection through-hole, and, the oxide & metal compound dielectric anti-copper-diffusion barrier layer are constituted by the said oxide layer and said metal layer.

The oxides layer 202 may be silicon SiCN, Si₃N₄, AlON, or Al₂O₃ , Ta₂O₅, HfO₂ or other metal oxides. The metal layer may be elemental metal such as Co, Ru, Ta, W, Mo, Ti, or Cu, and also may be metal nitride such as TaN, TiN, MoN or other metal nitride.

The oxide & metal compound dielectric anti-copper-diffusion barrier layer provided in the disclosure can be applied to different copper interconnection structures. The following is an embodiment for growing the oxide & metal compound dielectric anti-copper-diffusion barrier layer on the previous copper interconnection in the disclosure.

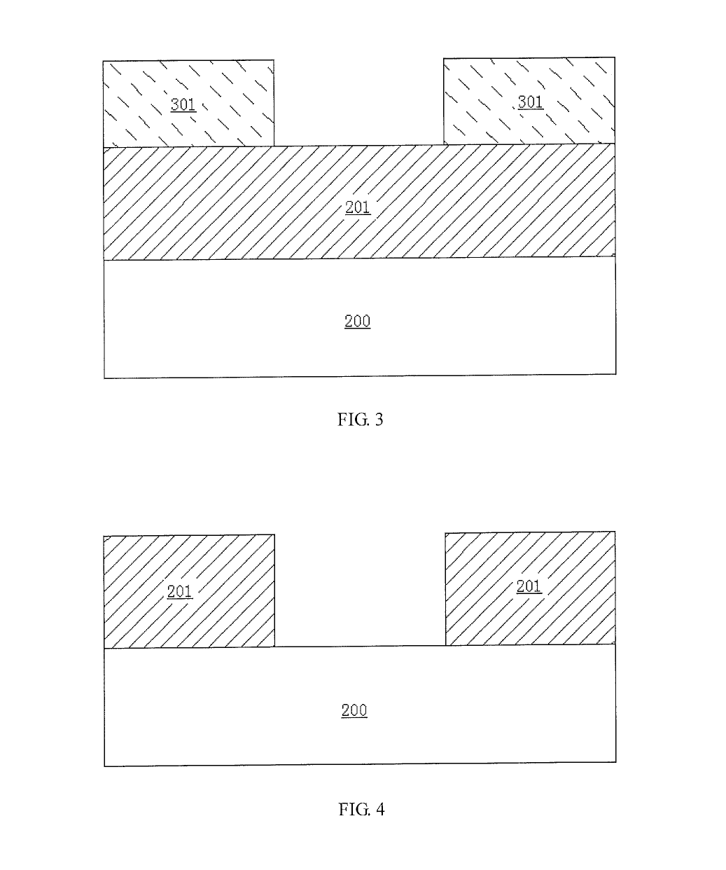

As shown in FIG. 3, at first, grow a low dielectric constant dielectric layer 201 on the surface of a provided semiconductor substrate 200, spin-coat photoresist 301 on the low dielectric constant dielectric layer 201, and define the positions of the interconnection through-hole by masking, exposing and developing.

The material of said semiconductor substrate 200 may be any one of monocrystalline silicon, polycrystalline silicon, or non-crystalline silicon, a silicon structure on an insulator, or an epitaxial layer structure on silicon. Said semiconductor substrate 200 is formed with a semiconductor device (not shown) inside, such the metal-oxide semiconductor device with a grid, a source and a drain. Said semiconductor substrate 200 can also be formed with a metal interconnection structure (not shown) inside, such as the copper through-hole or copper interconnection line.

Said low dielectric constant dielectric layer 201 may be silicon dioxide, borosilicate glass, phosphorosilicate glass, or boron-phosphorosilicate glass, and it can also be Ultra-low dielectric constant dielectric such as porous SiCOH (carbon-doped oxide) dielectric.

Second, etch off the low dielectric constant dielectric layer without protection of the photoresist to form interconnection through-hole. See FIG. 4 for the product after the photoresist 301 is etched off.

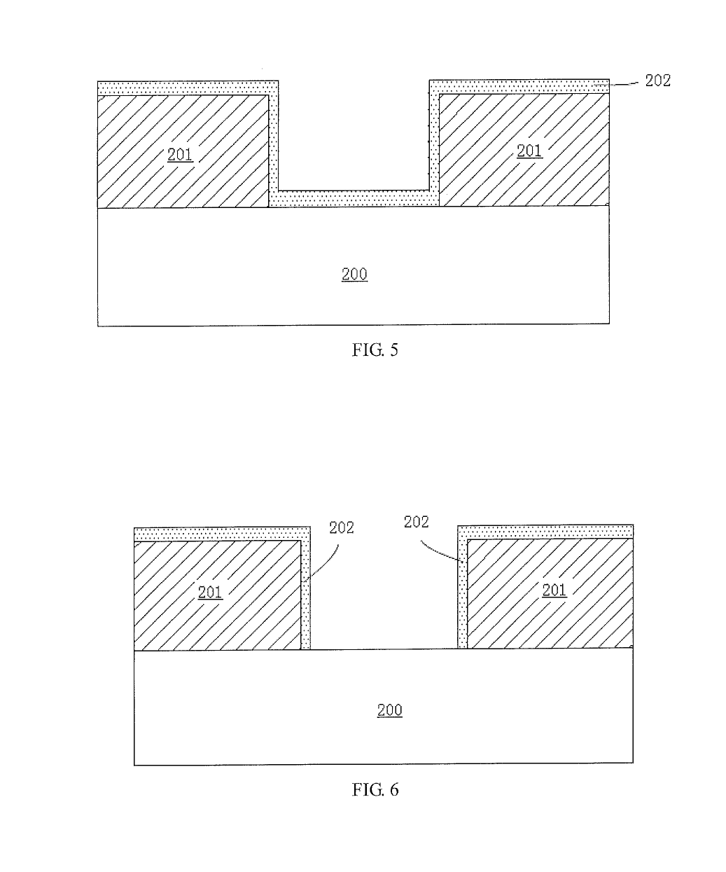

Third, grow 2 nm oxide layer 202 on the bottom and side walls of the interconnection through-hole and on the surface of the low dielectric constant dielectric layer 201, as shown in FIG. 5. And then etch the oxide layer on the bottom wall of the interconnection through-hole to ensure that the critical size using reactive ion etching (RIE) method, as shown in FIG. 6.

The oxide layer 202 may be silicon SiCN, Si₃N₄, AlON, Al₂O₃ , Ta₂O₅, or HfO₂. The method for growing the oxide layer described above is well known by in the field. As an example, the growth of SiCN oxide layer comprising, place a device formed with interconnect though-hole into a chamber heated to 300° C., using the TDMAS ([N(CH[RD₃])[RD₂]RD₃]SiH) as the precursor and the hydrogen (H₂) as the oxidant, and grow a SiCN oxide layer about 2 nm thick on the bottom and side walls of the interconnection through-hole and on the surface of the low dielectric constant dielectric layer 201 by the method of plasma-enhanced chemical vapor deposition (PECVD).

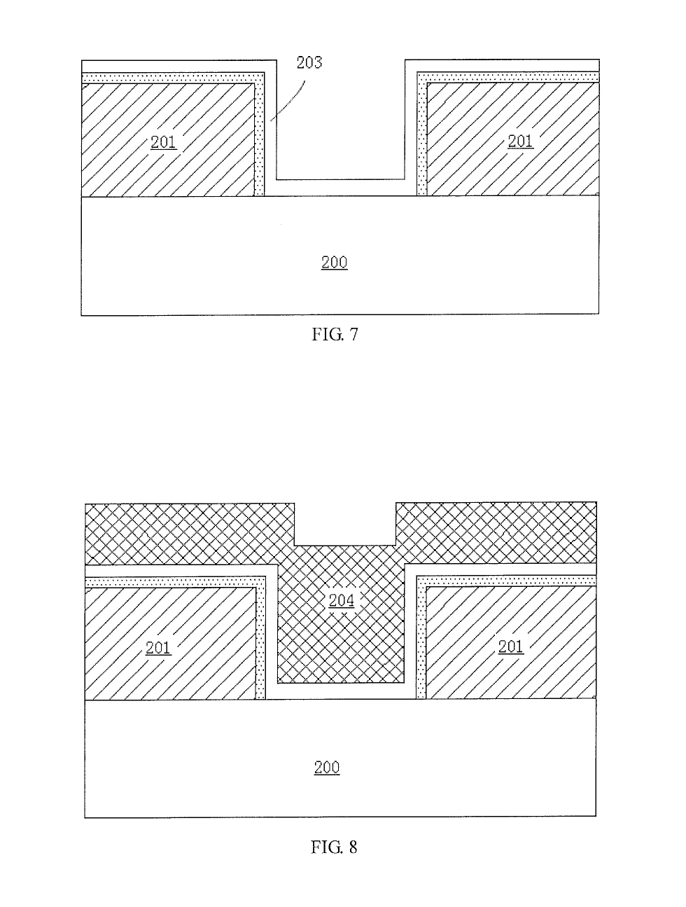

Fourth, grow a metal layer 203 about 1 nm thick covering the oxide layer 202 and the bottom wall of the interconnection through-hole by the method of atomic layer deposition, as shown in FIG. 7.

The metal layer 203 may be Co, Ru, Ta, W, Mo, Ti, or Cu, TaN, TiN, or MoN. The method for growing the metal layer described above is well known by in the field. As an example the growth of metal ruthenium comprising, heat the source of Ru IMBCHRu [(η6-1 -isopropyl-4-methyl benzol) (η4-hexamethylene-1,3-diene) ruthenium(O)] to 120° C. and use the IMBCHRu as the precursor and the oxygen (O₂) as the oxidant, in the reaction chamber heated to 300° C., and grow a metal Ru layer about 1 nm thick covering the oxide layer 202 and the bottom wall of the interconnection through-hole by the method of atomic layer deposition.

Fifth, electroplate the copper 204 in the interconnection through hole, as shown in FIG. 8.

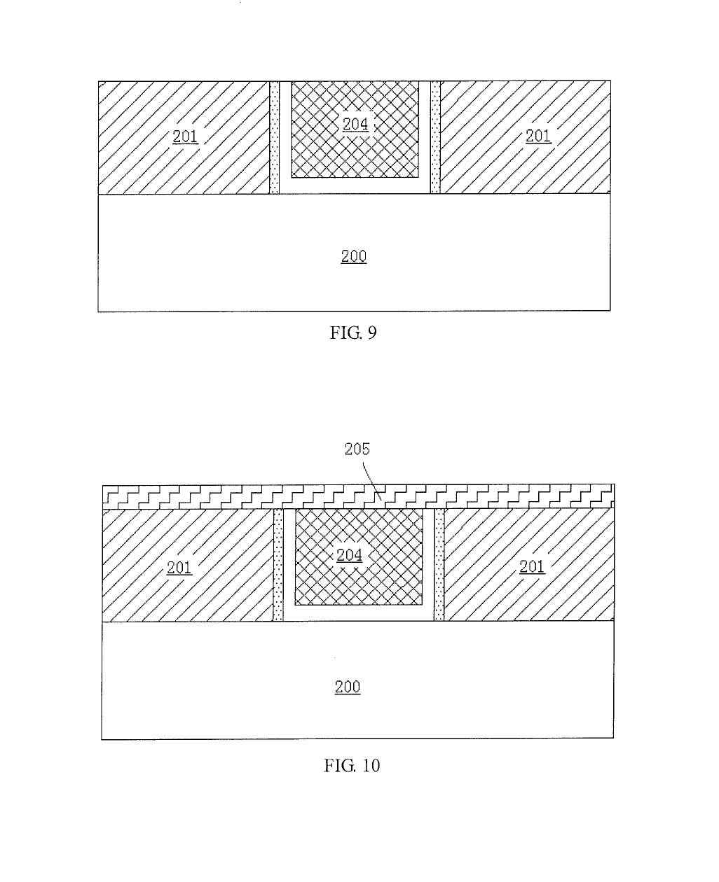

Sixth, chemically and mechanically polish the copper to remove abundant copper, anti-copper diffusion barrier layer and low dielectric constant dielectric layer, as shown in FIG. 9.

Seventh, grow a silicon nitride etched barrier layer 205 with the silane (SiH₄) and NH₃ as reaction gases by using plasma enhanced chemical vapor deposition (PECVD), as shown in FIG. 10.

As mentioned above, many embodiments with huge differences can be made within the spirit and scope of the disclosure. It should be known that except for those limited by the claims, the disclosure is not limited to the embodiment in the description.

1. A compound dielectric anti-copper-diffusion barrier layer for copper connections, which comprises a low dielectric constant dielectric layer formed on a semiconductor substrate, interconnection through-hole formed in the low dielectric constant dielectric layer, which characterized in that,
a oxide layer covering the side walls of said interconnection through-hole and formed on the top of said low dielectric constant dielectric layer,
a metal layer covering the said oxide layer and the bottom wall of said interconnection through-hole,
and, the oxide & metal compound dielectric anti-copper-diffusion barrier layer are constituted by the said oxide layer and said metal layer.

2. The compound dielectric anti-copper-diffusion barrier layer for copper connections according to claim 1 which characterized in that,
said oxide layer is silicon carbonitride, silicon nitride, metal oxides or metal oxynitride.

3. The compound dielectric anti-copper-diffusion barrier layer for copper connections according to claim 1 which characterized in that,
said metal layer is elemental metal or metal nitride.

4. The compound dielectric anti-copper-diffusion barrier layer for copper connections according to claim 2 which characterized in that,
said metal oxides is alumina, tantalum oxide or hafnium oxide, and said metal oxynitride is aluminum oxynitride.

5. The compound dielectric anti-copper-diffusion barrier layer for copper connections according to claim 3 which characterized in that,
said elemental metal is cobalt, ruthenium, tantalum, wolfram, molybdenum, titanium, or copper,
and said metal nitride is tantalum nitride, titanium nitride or molybdenum nitride.

6. A manufacturing method for a compound dielectric anti-copper-diffusion barrier layer for copper connections according to claim 1, comprising,
depositing a film of low dielectric constant dielectric layer on the surface of a provided semiconductor substrate;
etching said low dielectric constant dielectric layer to form interconnection through-hole;
growing a thin oxide layer covering the side and bottom wall of said interconnection through-hole and oxide layer and the surface of the low dielectric constant dielectric layer;
etching said oxide layer to remove the part of said oxide layer covering the bottom wall of said interconnection through-hole;
depositing a metal layer covering the left oxide layer and the bottom wall of said interconnection through-hole,
and the oxide & metal compound dielectric anti-copper-diffusion barrier layer are constituted by the said oxide layer and said metal layer.

7. The manufacturing method for a compound dielectric anti-copper-diffusion barrier layer for copper connections according to claim 6 which characterized in that,
said oxide layer is silicon carbonitride, silicon nitride, metal oxides or metal oxynitride.

8. The manufacturing method for a compound dielectric anti-copper-diffusion barrier layer for copper connections according to claim 6 which characterized in that,
said metal layer is elemental metal or metal nitride.

9. The manufacturing method for a compound dielectric anti-copper-diffusion barrier layer for copper connections according to claim 7 which characterized in that,
said metal oxides is alumina, tantalum oxide or hafnium oxide, and said metal oxynitride is aluminum oxynitride.

10. The manufacturing method for a compound dielectric anti-copper-diffusion barrier layer for copper connections according to claim 8 which characterized in that,
said elemental metal is Cobalt, ruthenium, tantalum, wolfram, molybdenum, titanium, or copper,
and said metal nitride is tantalum nitride, titanium nitride or molybdenum nitride.
